(19) United States
(12) Patent Application Publication
(10) Pub. No.: US 2006/0143352 A1
(43) Pub. Date: Jun. 29, 2006

(54) Electronic device having memory card detachment/attachment recognition function and method therefor

(75) Inventor: Sung-Zun Park, Seoul (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Pantech Co., Ltd.

(21) Appl. No.: 11/321,172

(22) Filed: Dec. 28, 2005

(30) Foreign Application Priority Data
Dec. 29, 2004 (KR) 10-2004-0115102

(51) Int. Cl. H05K 7/10; G06F 13/00

(52) U.S. Cl. 710/301

(57) ABSTRACT

An electronic device with a memory card detachment/attachment recognition function and method therefor is provided. The inventive electronic device and method can protect data in a memory card and preventing a malfunctioning by recognizing a detachment/attachment of the memory card that may occur due to an opening of the memory cover. The inventive electronic device comprises a memory card that is detachable/attachable from/to the electronic device, a cover for protecting the memory card, a cover opening signal generator for generating a cover opening signal when the cover is open, and a controller for judging whether the memory card is detached or attached and controlling a connection to the memory card based on the cover opening signal from the cover opening signal generator and the judgment result.

### FIELD OF THE INVENTION

The present invention relates to an electronic equipment with a memory card detachment/attachment recognition function and method therefor; and more particularly, to an electronic equipment and method capable of protecting data in a memory card and preventing a malfunctioning by recognizing a detachment/attachment of the memory card that may occur due to an opening of a memory cover.

### DESCRIPTION OF RELATED ART

Electronic equipments refer to equipments such as a wireless communication terminal, notebook computer, camcorder, digital camera, portable multimedia player (PMP), etc., from/to which a memory card is detachable/attachable.

Among those equipments, it is known that the wireless communication terminal denotes a terminal capable of wireless communication while each individual carries such a terminal as PCS (personal communication services) terminal, PDA (personal digital assistant) terminal, smart phone, IMT-2000 (International Mobile Telecommunication-2000) terminal, wireless LAN terminal, or the like.

For the sake of illustration, the wireless communication terminal among the equipments will be given in the following embodiment.

The greatest advantage of such wireless communication terminal among other things is that it can provide calling and called users with mobility. Due to such mobility, the number of wireless communication subscribers has been increased in a geometrical progression, and the wireless communication terminal has widely been used by the general public in recent years.

However, as time goes on, such mobility merit is gradually forgotten from the users of the wireless communication terminal; and, instead, a multi-function wireless communication terminal capable of offering more various supplementary services is required.

According to such requirement, most of recently developed and sold wireless communication terminals are provided with functions such as radio broadcasting reception, music reproduction (e.g., MP3, MPEG layer 3, etc.), finger-pressure, blood sugar level sensing, ultrasound photographing, and so on, including a camera function. Especially, the music reproduction function is one of the functions spotlighted by the younger generation.

In the meantime, as the supplementary services as presented above are added to the wireless communication terminal, required capacity of memory also becomes large. For example, in order to store an image file after taking pictures using the wireless communication terminal, or music file for the music reproduction, the required capacity of memory becomes large accordingly.

Using the memory built in the wireless communication terminal merely, however, a physical limitation has existed to store the large capacity multimedia file as given above.

Hence, in recent years, a memory card detachable/attachable from/to the wireless communication terminal has been employed when an additional memory capacity is necessary.

In the prior art, however, in case that the detachable/attachable memory card is detached or attached from or to the wireless communication terminal after storing any data therein, the terminal can not recognize a time when the memory card is detached or attached.

For the above reason, when the memory card is detached by a user, there sometimes occurs an instance where the wireless communication terminal tries to store data in the memory card, or make a connection to the memory card to read out data stored therein.

Accordingly, due to the connection to the memory card when the memory card is caused to be detached, the wireless communication terminal is reset, or the data stored in the memory card is erased, leading to a hot rejection phenomenon where the wireless communication terminal malfunctions.

### SUMMARY OF THE INVENTION

It is, therefore, a primary object of the present invention to provide an electronic device and method capable of protecting data in a memory card and preventing a malfunctioning by recognizing a detachment/attachment of the memory card that may occur due to an opening of a memory cover.

In accordance with one aspect of the present invention, there is provided an electronic device with a memory card detachment/attachment recognition function, the electronic device comprising: a memory card that is detachable/attachable from/to the electronic device; a cover for protecting the memory card; a cover opening signal generator for generating a cover opening signal when the cover is open; and a controller for judging whether the memory card is detached or attached and controlling a connection to the memory card based on the cover opening signal from the cover opening signal generator and the judgment result.

In accordance with another aspect of the present invention, there is provided a method for recognizing a detachment or attachment of a memory card in an electronic device, comprising the steps of: providing a logic high signal to a cover opening signal generator when a memory cover is open; generating a cover opening signal at the cover opening generator in response to the logic high signal; and controlling a connection to the memory card based on the cover opening signal and a current state (detachment or attachment) of the memory card.

The other objectives and advantages of the invention will be understood by the following description and will also be appreciated by the embodiments of the invention more clearly. Further, the objectives and advantages of the invention will readily be seen that they can be realized by the means and its combination specified in the claims.

### BRIEF DESCRIPTION OF THE DRAWINGS

The above and other objects and features of the instant invention will become apparent from the following description of preferred embodiments taken in conjunction with the accompanying drawings, in which:

FIGS. 1A and 1B are exemplary configuration diagrams showing an embodiment of a wireless communication terminal with a memory card detachment/attachment recognition function in accordance with the present invention;

FIG. 2 is an exemplary circuitry diagram illustrating an embodiment of the memory cover opening signal generator in accordance with the present invention shown in FIG. 3; and

FIG. 3 is an exemplary flowchart illustrating a method for determining whether the memory card is detached or attached from and to the wireless communication terminal in accordance with the present invention.

### DETAILED DESCRIPTION OF THE INVENTION

The above-mentioned objectives, features, and advantages will be more apparent by the following detailed description in association with the accompanying drawings; and, according to this, the technical spirit of the invention will readily be conceived by those skilled in the art to which the invention belongs. Further, in the following description, well-known arts will be not described in detail if they would obscure the gist of the invention in unnecessary detail. Hereinafter, a preferred embodiment of the present invention will be described in detail with reference to the accompanying drawings.

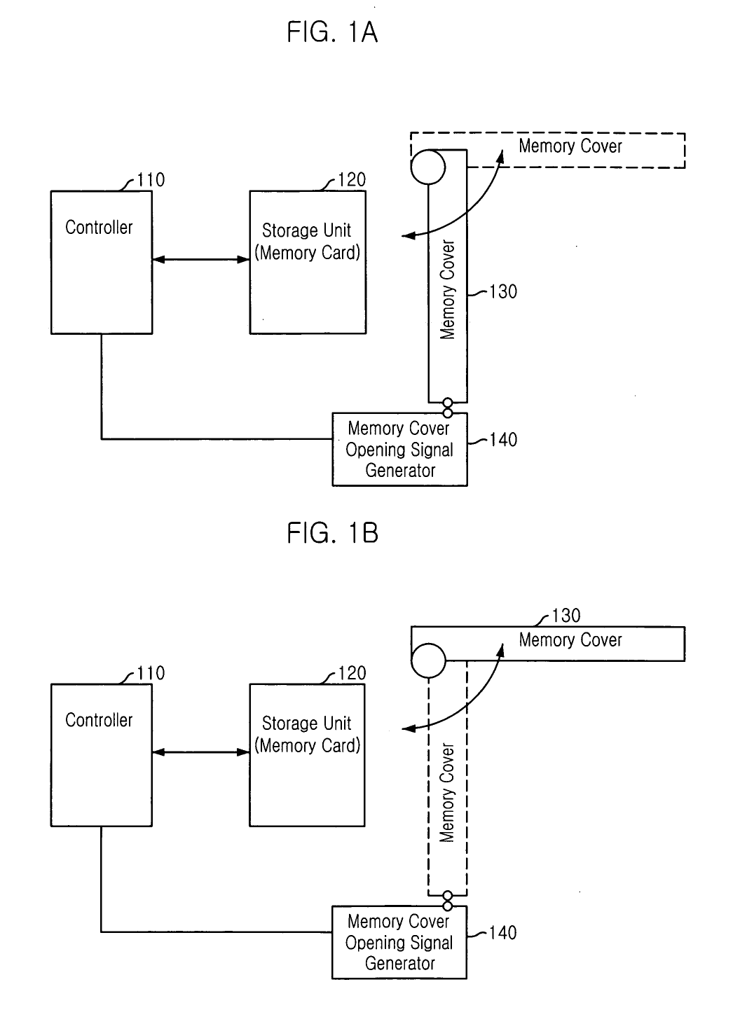

FIGS. 1A and 1B are exemplary configuration diagrams showing an embodiment of a wireless communication terminal with a memory card detachment/attachment recognition function in accordance with the present invention.

As illustrated in FIG. 1A and 1B, the inventive wireless communication terminal with the memory card detachment/attachment recognition function comprises a storage unit 120 that is detachable/attachable from/to the wireless communication terminal, a memory cover 130 for protecting the storage unit 120 from an external impact, a memory cover opening signal generator 140 for generating a memory cover opening signal when the memory cover 130 is open, and a controller 110 for controlling a connection to the storage means 120 based on the memory cover opening signal from the memory cover opening signal generator 140 and a current state (detachment or attachment) of the storage unit 120.

Further, the storage unit 120 includes a memory card that is a small-sized storage device and fabricated in a nonvolatile memory such as a flash memory, etc., which is detachable/attachable from/to the wireless communication terminal. In the following embodiment, the storage unit 120 will be given as the detachable/attachable memory card for the purpose of illustration.

The controller 110 serves to control the entire operation of the wireless communication terminal and also control the operation of each element contained therein.

It is also the role of the controller 110 to control a connection to the storage unit 120 on the basis of the memory cover opening signal from the memory cover opening signal generator 140 and a current state (detachment or attachment) of the storage unit 120.

For example, if the controller 110 senses the memory cover opening signal in a state that the memory card is attached, it judges that the memory card would be detachable and halts the connection to the memory card.

On the other hands, if the controller 110 senses the memory cover opening signal in a state that the memory card is detached, it judges that the memory card would be attachable and begins a connection to the memory card since then.

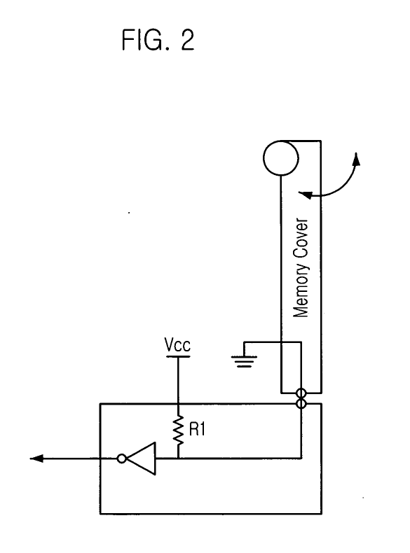

The memory cover opening signal generator 140 includes a pull-up resistor R1 and an inverter, as illustrated in FIG. 2. This memory cover opening signal generator 140 creates a different signal according to whether the memory cover 130 is open or close. Specifically, when the memory cover 130 is close, the inverter in the memory cover opening signal generator 140 is connected to a contact point of the memory cover 130 that is electrically grounded, and receives a logic low signal. In response to the received logic low signal, the memory cover opening signal generator 140 creates a logic high signal.

In contrast, when the memory cover 130 is open, the inverter receives a logic high signal by virtue of the pull-up resistor. Based on the received logic high signal, the memory cover opening signal generator 140 creates a logic low signal.

The logic low signal, which is created by the memory cover opening signal generator 140 when the memory cover 130 is open, indicates the memory cover opening signal, as mentioned above.

The controller 110 recognizes, when the memory cover opening signal is applied from the memory cover opening signal generator 140 thereto, the memory cover to be open, and determines a detachment or attachment of the memory card by taking account into a current state (detachment or attachment) thereof.

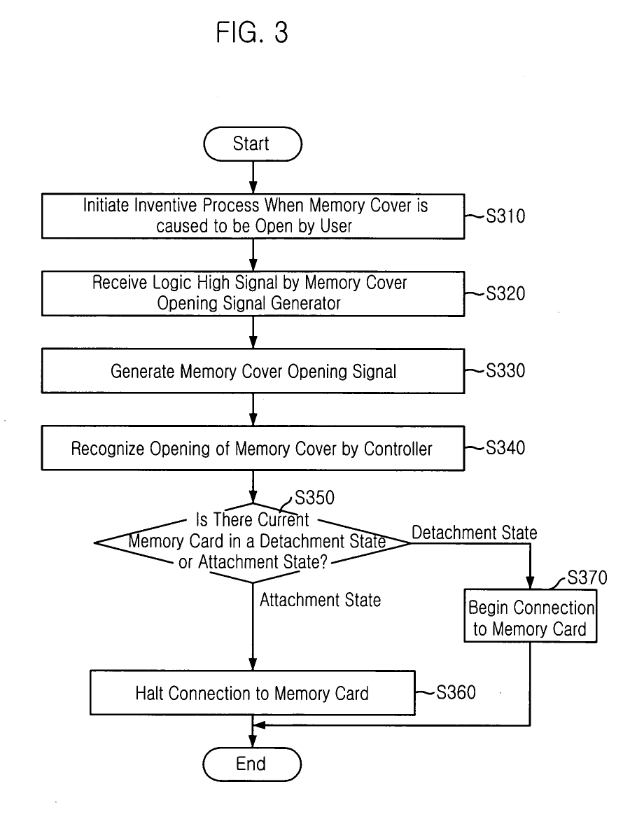

FIG. 3 is an exemplary flowchart illustrating an embodiment of a method for determining whether the memory card is detached or attached from and to the wireless communication terminal in accordance with the present invention.

Firstly, at step S310, the inventive process initiates when the memory cover 130 is caused to be open by a user. When the memory cover 130 is open, the memory cover opening signal generator 140 receives a logic high signal by means of the pull-up resistor at step S320.

As set forth in the foregoing, when the memory cover 130 is close, the memory cover opening signal generator 140 receives a logic low signal because the contact point of the memory cover 130 coupled with the generator 140 is in the ground state, while; when the memory cover 130 is open, the memory cover opening signal generator 140 receives a logic high signal.

Subsequently, at step S330, the memory cover opening signal generator 140 generates, in response to the received logic high signal, the logic low signal, i.e., the memory cover opening signal.

If the memory cover opening signal is issued as set forth above, the controller 110 recognizes at step S340 that the memory cover 130 is open. And then, the controller 110 judges at step S350 whether the memory card 120 is detached or attached by sensing a current state thereof.

As a result of the judging process at step S350, if the memory card is attached, the controller 110 recognizes that the memory cover opening signal is a signal for a detachment of the memory card, and then halts the connection to the memory card at step S360.

Meanwhile, if it is judged at step S350 that the memory card is detached, the controller 110 recognizes that the memory cover opening signal is a signal for an attachment of the memory card, and thereafter begins a connection to the memory card at step S370.

In the foregoing, it should be noted that the opening of the memory cover 130 does not always imply the detachment/attachment of the memory card 120. Namely, the memory cover 130 may be open in order to watch for a contact state of the memory card 120, or remove impurities within the memory card 120.

In the meantime, in case that the memory cover 130 is open for the above reasons, there may be no problem if the memory card is detached, but may be a problem if the memory card is attached. That is, in case that the memory cover 130 is open and the memory card is attached, the controller 110 halts the connection to the memory card 120 and hence the wireless communication terminal does not normally operate because of such memory cover's opening although the memory card 120 is not actually detached.

Accordingly, the controller 110 of the invention recognizes the detachment of the memory card 120 and halts the connection to the memory card and, at the same time, motivates a timer to be operated by setting a predefined time. After passing through the predefined time, the controller 110 confirms if the memory card 120 is actually detached.

In the confirmation process, if the memory card 120 is actually detached, the controller 110 maintains the halt state of the connection to the memory card 120, while, if the memory card 120 is not detached, the controller 110 promptly resumes the connection to the memory card 120.

Alternatively, it may be implemented that, without using the timer, the connection to the memory card is resumed by means of a manipulation of a certain button or menu by a user.

As described above, the present invention can protect data in the memory card by recognizing the detachment/attachment of the memory card by the opening sensing of the memory cover 130.

Moreover, the invention is capable of preventing the wireless communication terminal from resetting by recognizing the detachment/attachment of the memory card.

The inventive method as disclosed in the foregoing may be implemented by a program which is made in a computer readable manner and stored in a storage medium such as CD-ROM, floppy disk, hard disk, optical magnetic disk, or the like. Since this process could readily be conceived by those skilled in the art, details thereof will be omitted here for the sake of brevity.

As a result, the present invention has some effects as follows. Firstly, the invention can protect data in the memory card by recognizing the detachment/attachment of the memory card by the opening sensing of the memory cover 130.

Secondly, the invention is capable of preventing the electronic device from resetting by recognizing the detachment/attachment of the memory card.

The present application contains subject matter related to Korean patent application No. 2004-115102, filed with the Korean Intellectual Property Office on Dec. 29, 2004, the entire contents of which are incorporated herein by reference.

While the present invention has been described with respect to the particular embodiments, it will be apparent to those skilled in the art that various changes and modifications may be made without departing from the spirit and scope of the invention as defined in the following claims.

What is claimed is:

1. An electronic device with a memory card detachment/attachment recognition function, the electronic device comprising:
a memory card that is detachable/attachable from/to the electronic device;
a cover for protecting the memory card;
a cover opening signal generator for generating a cover opening signal when the cover is open; and
a controller for judging whether the memory card is detached or attached and controlling a connection to the memory card based on the cover opening signal from the cover opening signal generator and the judgment result.

2. The electronic device as recited in claim 1, wherein the cover opening signal has a logic high value when the cover is close, and a logic low value when the cover is open.

3. The electronic device as recited in claim 1, wherein the cover opening signal generator comprises:
an inverter for inverting an inputted signal value; and
a pull-up resistor for providing a logic high signal to the inverter.

4. The electronic device as recited in claim 3, wherein the cover opening signal generator generates a cover opening signal having logic low value in accordance with the logic high signal provided from the pull-up resistor when the cover is open.

5. The electronic device as recited in claim 4, wherein the controller halts, if the cover opening signal is received in a state that the memory card is attached, a connection to the memory card by sensing a detachment of the memory card, and begins, if the cover opening signal is received in a state that the memory card is detached, a connection to the memory card by sensing an attachment of the memory card.

6. A method for recognizing a detachment or attachment of a memory card in an electronic device, comprising the steps of:
providing a logic high signal to a cover opening signal generator when a memory cover is open;
generating, at the cover opening signal generator, a cover opening signal in response to the logic high signal; and
controlling a connection to the memory card based on the cover opening signal and a current state (detachment or attachment) of the memory card.

7. The method as recited in claim 6, wherein the controlling step comprises the steps of:
if the cover opening signal is provided in a state that the memory card is attached, recognizing the cover opening signal as a signal for a detachment of the memory card and halting a connection to the memory card; and
if the cover opening signal is provided in a state that the memory card is detached, recognizing the cover opening signal as a signal for an attachment of the memory card and beginning a connection to the memory card.
